(19) United States
(12) Patent Application Publication
(10) Pub. No.: US 2024/0060205 A1
(43) Pub. Date: Feb. 22, 2024

(54) Method for Improving Copper Alloy Electroplating Filling Process

(71) Applicant: Shanghai Huali Integrated Circuit Corporation, Shanghai (CN)

(72) Inventor: Yu Bao, Shanghai (CN)

(73) Assignee: Shanghai Huali Integrated Circuit Corporation, Shanghai (CN)

(21) Appl. No.: 18/125,908

(22) Filed: Mar. 24, 2023

(30) Foreign Application Priority Data
Aug. 22, 2022 (CN) 202211005664.8

(51) Int. Cl. C25D 5/02; C25D 7/12; C25D 3/38; C25D 3/58; C25D 21/14; H01L 21/768

(52) U.S. Cl. CPC C25D 5/02; C25D 7/123; C25D 3/38; C25D 3/58; C25D 21/14; H01L 21/76873; H01L 21/76879; H01L 21/76883

(57) ABSTRACT

The present application provides a method for improving a copper alloy electroplating filling process, forming a groove on a semiconductor structure; forming a barrier layer on the surface of the groove, and then covering the barrier layer with a seed layer; electroplating the seed layer in the groove with copper, until an upper surface of the copper in the groove is close to an opening of the groove; adding impurity metal ions into an electroplating solution for copper electroplating to continue the electroplating, wherein during an electroplating process, the impurity metal ions are fully consumed quickly, forming an alloy layer on the surface of the copper; continuing the copper electroplating on the alloy layer in the groove; repeating steps 4 and 5 until the groove is fully filled; and performing chemical mechanical polishing, the polishing ending at the opening of the groove.

### CROSS-REFERENCE TO RELATED APPLICATIONS

This application claims priority to Chinese patent application No. 202211005664.8, filed on Aug. 22, 2022, the disclosure of which is incorporated herein by reference in its entirety.

### TECHNICAL FIELD

The present application relates to the technical field of semiconductors, in particular to a method for improving a copper alloy electroplating filling process.

### BACKGROUND

Among the methods for improving electron migration (EM), a mainstream approach in the industry is alloy seed crystal. However, this approach may significantly increase the resistance, because a large number of alloy elements remain in the seed layer, while the relative length unit is increased mainly by distributing the alloy elements on the upper surface of copper, i.e., an interface with the dielectric barrier. Another approach requires a long time of heating of the copper surface dopant, which is a great challenge to the thermal balance.

Recently, Cu (Ag) alloy electroplating has been proved. One advantage of this method lies in achieving uniform Cu doping over the entire thickness of the interconnection. However, the electroplating process becomes more complex. Compared with the electroplating process, the PVD process is easier to control the dopant concentration in the deposition layer. Currently, the addition of a dopant to a plating solution is still in the research stage.

### BRIEF SUMMARY

In view of the above defect in the prior art, the objective of the present application is to provide a method for improving a copper alloy electroplating filling process, so as to solve the problem of a significant increase in copper wire resistance caused by a principal alloy during a copper alloy electroplating filling process in the prior art.

In order to achieve the above objective and other related objectives, the present application provides a method for improving a copper alloy electroplating filling process. The method for improving a copper alloy electroplating filling process at least includes the following steps:
step 1, providing a semiconductor structure, and forming a groove on the semiconductor structure;
step 2, forming a barrier layer on the surface of the groove, and then covering the barrier layer with a seed layer;
step 3, electroplating the seed layer in the groove with copper, until an upper surface of the copper in the groove is close to an opening of the groove;
step 4, adding impurity metal ions into an electroplating solution for copper electroplating to continue the electroplating, wherein during an electroplating process, the impurity metal ions are fully consumed quickly, forming an alloy layer on the surface of the copper;
step 5, continuing the copper electroplating on the alloy layer in the groove;
step 6, repeating steps 4 and 5 until the groove is fully filled; and
step 7, performing chemical mechanical polishing, the polishing ending at the opening of the groove.

In an example, a method of forming the groove on the semiconductor structure in step 1 is: forming the groove on the semiconductor structure by means of lithography and etching.

In an example, in step 2, the groove on the semiconductor structure undergoes wet cleaning before the barrier layer and seed layer are formed on the surface of the groove.

In an example, in step 3, the seed layer in the groove is electroplated with the copper by an electrochemical electroplating process.

In an example, in step 3, the seed layer in the groove is electroplated with the copper by means of the electroplating solution.

In an example, in step 4, the impurity metal ions are added into the electroplating solution in a manner of intermittent injection.

In an example, in step 4, the impurity metal ions in the electroplating solution are Ag ions.

In an example, in step 4, the concentration of the impurity metal ions in the electroplating solution is 0.1-5 g/L.

In an example, in step 4, the impurity metal ions are added into the electroplating solution by adding a solution containing the impurity metal ions into the electroplating solution.

In an example, in step 4, during an intermittent injection process, the volume of the solution for a single injection is less than 50 ml, and the concentration of the solution is 1-40 g/L.

In an example, in step 4, during the intermittent injection process, the solution is added in a manner of a variable injection rate.

As stated above, the method for improving a copper alloy electroplating filling process of the preset application has the following beneficial effects: according to the present application, a copper layer is doped with impurity metal deposited therein by means of alloy electroplating to form the alloy layer, optimizing distribution of the impurity metal in a copper wire, thus improving the electron migration and avoiding a significant increase in the resistance of the copper wire caused by the principal alloy.

### BRIEF DESCRIPTION OF THE DRAWINGS

FIGS. 1-7 are schematic diagrams of structures in various steps of electroplating copper and forming an alloy layer according to the present application.

FIG. 8 is a flowchart of a method for improving a copper alloy electroplating filling process according to the present application.

### DETAILED DESCRIPTION OF THE DISCLOSURE

The embodiments of the present application are described below using specific examples, and those skilled in the art can easily understand other advantages and effects of the present application from the contents disclosed in the Description. The present application can also be implemented or applied using other different specific embodiments, and various details in the Description can also be modified or changed based on different viewpoints and applications without departing from the spirit of the present application.

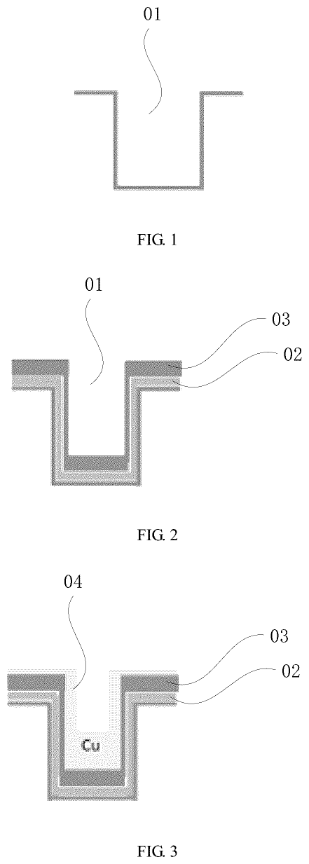

Please refer to FIGS. 1-8. It should be noted that the drawings provided in this embodiment are only used to illustrate the basic concept of the present application in a schematic way, so the drawings only show the components related to the present application rather than being drawn according to the number, shape and size of the components in actual implementation. The type, number and proportion of various components can be changed randomly during actual implementation, and the layout of components may be more complicated.

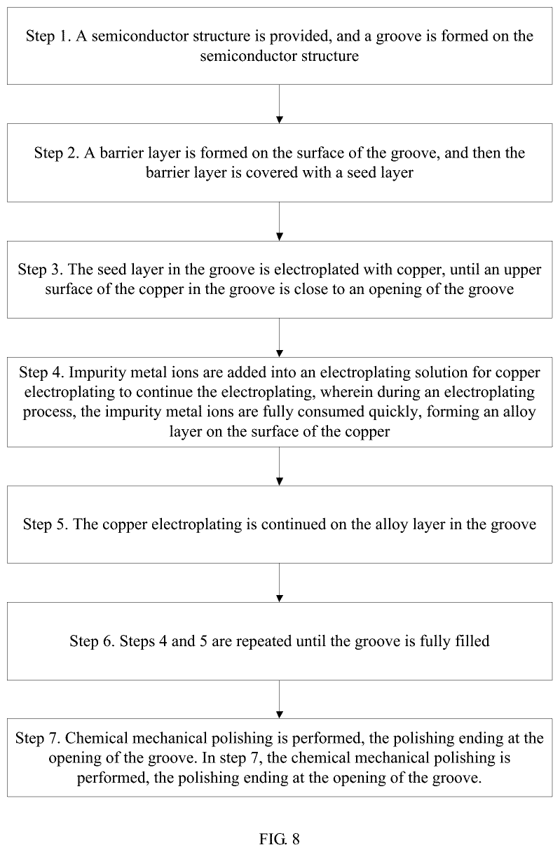

The present application provides a method for improving a copper alloy electroplating filling process, referring to FIG. 8, at least including the following steps.

Step 1. A semiconductor structure is provided, and a groove is formed on the semiconductor structure.

In this embodiment of the present application, a method of forming the groove on the semiconductor structure in step 1 is: forming the groove on the semiconductor structure by means of lithography and etching.

Referring to FIG. 1, FIG. 1 illustrates a schematic diagram of a structure of the groove formed on the semiconductor structure in the present application. In step 1, the semiconductor structure is provided, and the groove 01 is formed on the semiconductor structure.

Step 2. A barrier layer is formed on the surface of the groove, and then the barrier layer is covered with a seed layer.

In this embodiment of the present application, the groove on the semiconductor structure undergoes wet cleaning before the barrier layer and seed layer are formed on the surface of the groove. Referring to FIG. 2, in step 2, the barrier layer 02 is formed on the surface of the groove 01, and then the barrier layer 02 is covered with the seed layer 03; and the groove 01 on the semiconductor structure undergoes the wet cleaning before the barrier layer 02 and seed layer 03 are formed on the surface of the groove 01.

Step 3. The seed layer in the groove is electroplated with copper, until an upper surface of the copper in the groove is close to an opening of the groove.

In this embodiment of the present application, in step 3, the seed layer in the groove is electroplated with the copper by an electrochemical electroplating process.

In this embodiment of the present application, in step 3, the seed layer in the groove is electroplated with the copper by means of the electroplating solution.

Referring to FIG. 3, in step 3, the seed layer 03 in the groove is electroplated with copper 04, until an upper surface of the copper 04 in the groove is close to an opening of the groove (FIG. 3 does not show that the upper surface of the copper in the groove is close to the opening of the groove). In this embodiment, the seed layer 03 in the groove is electroplated with the copper 04 by the electrochemical electroplating process. In this embodiment the seed layer 03 in the groove is electroplated with the copper 04 by means of the electroplating solution.

Step 4. Impurity metal ions are added into an electroplating solution for copper electroplating to continue the electroplating, wherein during an electroplating process, the impurity metal ions are fully consumed quickly, forming an alloy layer on the surface of the copper.

In this embodiment of the present application, in step 4, the impurity metal ions are added into the electroplating solution in a manner of intermittent injection.

In this embodiment of the present application, in step 4, the impurity metal ions in the electroplating solution are Ag ions.

In this embodiment of the present application, in step 4, the concentration of the impurity metal ions in the electroplating solution is 0.1-5 g/L.

In this embodiment of the present application, in step 4, the impurity metal ions are added into the electroplating solution by adding a solution containing the impurity metal ions into the electroplating solution.

In this embodiment of the present application, in step 4, during an intermittent injection process, the volume of the solution for a single injection is less than 50 ml, and the concentration of the solution is 1-40 g/L.

In this embodiment of the present application, in step 4, during the intermittent injection process, the solution is added in a manner of a variable injection rate.

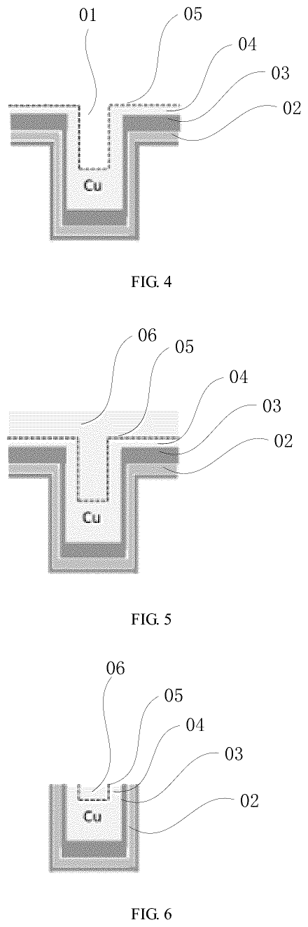

Referring to FIG. 4, in step 4, the impurity metal ions are added into the electroplating solution for copper 04 electroplating to continue the electroplating, wherein during the electroplating process, the impurity metal ions are fully consumed quickly, forming the alloy layer 05 on the surface of the copper 04. The impurity metal ions are added into the electroplating solution in the manner of intermittent injection. The impurity metal ions in the electroplating solution are Ag ions. The concentration of the impurity metal ions in the electroplating solution is 0.1-5 g/L. The impurity metal ions are added into the electroplating solution by adding the solution containing the impurity metal ions into the electroplating solution. During the intermittent injection process, the volume of the solution for a single injection is less than 50 ml, and the concentration of the solution is 1-40 g/L. During the intermittent injection process, the solution is added in the manner of a variable injection rate.

Step 5. The copper electroplating is continued on the alloy layer in the groove. Referring to FIG. 5, in other embodiments, in step 5, the copper electroplating is continued on the alloy layer in the groove until the copper 06 fully fills the groove. Then chemical mechanical polishing is performed, the polishing ending at the opening of the groove, so as to form a structure shown in FIG. 6.

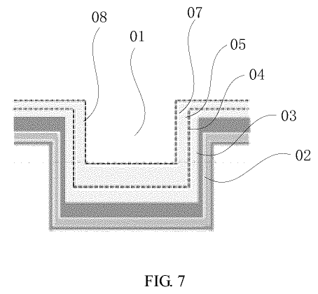

Step 6. Steps 4 and 5 are repeated until the groove is fully filled. Referring to FIG. 7, in step 6, after the alloy layer 05 is formed, step 4 is repeated to perform electroplating with copper 07, and then step 5 is repeated to form an alloy layer 08 on the electroplating copper 07. In different embodiments, the number of times of repeating steps 4 and 5 is determined according to the width of the opening of the groove. That is, the number of electroplating copper and alloy layers is determined according to different widths of the opening of the groove. Steps 4 and 5 are repeated until the groove is finally fully filled.

Step 7. Chemical mechanical polishing is performed, the polishing ending at the opening of the groove. In step 7, the chemical mechanical polishing is performed, the polishing ending at the opening of the groove.

To sum up, according to the present application, a copper layer is doped with impurity metal deposited therein by means of alloy electroplating to form the alloy layer, optimizing distribution of the impurity metal in a copper wire, thus improving the electron migration and avoiding a significant increase in the resistance of the copper wire caused by the principal alloy. Therefore, the present application effectively overcomes various defects in the prior art and thus has high industrial utilization value.

The above embodiment merely illustrates the principle and effect of the present application, rather than limiting the present application. Anyone skilled in the art can modify or change the above embodiment without departing from the spirit and scope of the present application. Therefore, all equivalent modifications or changes made by those with ordinary knowledge in the art without departing from the spirit and technical idea disclosed in the present application shall still be covered by the claims of the present application.

What is claimed is:

1. A method for improving a copper alloy electroplating filling process, at least comprising the following steps:
step 1, providing a semiconductor structure, and forming a groove on the semiconductor structure;
step 2, forming a barrier layer on a surface of the groove, and then covering the barrier layer with a seed layer;
step 3, electroplating the seed layer in the groove with copper, until an upper surface of the copper in the groove is close to an opening of the groove;
step 4, adding impurity metal ions into an electroplating solution for copper electroplating to continue the electroplating, wherein during an electroplating process, the impurity metal ions are fully consumed quickly, forming an alloy layer on the surface of the copper;
step 5, continuing the copper electroplating on the alloy layer in the groove;
step 6, repeating steps 4 and 5 until the groove is fully filled; and
step 7, performing chemical mechanical polishing, the polishing ending at the opening of the groove.

2. The method for improving the copper alloy electroplating filling process according to claim 1, wherein a method of forming the groove on the semiconductor structure in step 1 is: forming the groove on the semiconductor structure by means of lithography and etching.

3. The method for improving the copper alloy electroplating filling process according to claim 1, wherein in step 2, the groove on the semiconductor structure undergoes wet cleaning before the barrier layer and the seed layer are formed on the surface of the groove.

4. The method for improving the copper alloy electroplating filling process according to claim 1, wherein in step 3, the seed layer in the groove is electroplated with the copper by an electrochemical electroplating process.

5. The method for improving the copper alloy electroplating filling process according to claim 1, wherein in step 3, the seed layer in the groove is electroplated with the copper by means of the electroplating solution.

6. The method for improving the copper alloy electroplating filling process according to claim 1, wherein in step 4, the impurity metal ions are added into the electroplating solution in a manner of intermittent injection.

7. The method for improving the copper alloy electroplating filling process according to claim 1, wherein in step 4, the impurity metal ions in the electroplating solution are Ag ions.

8. The method for improving the copper alloy electroplating filling process according to claim 1, wherein in step 4, a concentration of the impurity metal ions in the electroplating solution is 0.1-5 g/L.

9. The method for improving the copper alloy electroplating filling process according to claim 1, wherein in step 4, the impurity metal ions are added into the electroplating solution by adding a solution containing the impurity metal ions into the electroplating solution.

10. The method for improving the copper alloy electroplating filling process according to claim 9, wherein in step 4, during an intermittent injection process, a volume of the solution for a single injection is less than 50 ml, and a concentration of the solution is 1-40 g/L.

11. The method for improving the copper alloy electroplating filling process according to claim 10, wherein in step 4, during the intermittent injection process, the solution is added in a manner of a variable injection rate.
